(19) United States
(12) Patent Application Publication
(10) Pub. No.: US 2009/0293950 A1
(43) Pub. Date: Dec. 3, 2009

(54) Photovoltaic Cell

(75) Inventors: Peter Chabrecek, Freidorf (CH); Egbert Figgemeier, Hausen im Wiesental (DE); Uwe Pieles, Mullheim/Baden (DE)

Correspondence Address: BACHMAN & LAPOINTE, P.C., 900 CHAPEL STREET, SUITE 1201, NEW HAVEN, CT, 06510, US

(73) Assignees: SEFAR AG, Thal (CH); THE UNIVERSITY OF BASEL, Basel (CH); FACHHOCHSCHULE NORDWESTSCHWEIZ, Muttenz (CH)

(21) Appl. No.: 12/300,835

(22) PCT Filed: May 14, 2007
(86) PCT No.: PCT/EP07/04256

§ 371 Date: Jul. 16, 2009

(30) Foreign Application Priority Data
May 18, 2006 (DE) 10 2006 023 638.6

(51) Int. Cl. H01L 31/0216; H01L 31/18

(52) U.S. Cl. 136/256; 438/85; 257/E21.09; 257/E31.015

(57) ABSTRACT

A photovoltaic cell, particularly a color-sensitized solar cell, comprises a conductive support substrate, coated with a metal oxide semiconductor layer, a color layer embodied so as to electronically interact with the metal oxide semiconductor layer, an electrolyte later that is applied to the color layer, and a counter-electrode which is connected to the electrolyte layer. The support substrate and/or the counter-electrode is/are made from a flexible fabric composed of a plurality of interwoven fibers.

### BACKGROUND

(1) Field of the Invention

The present invention relates to a photovoltaic cell according to the preamble of the main claim, in particular a so-called dye-sensitized, nanostructure solar cell (DNSC=DYE-SENSITIZED NANO STRUCTURE SOLAR CELL), wherein the invention is equally suitable for other solar cell technologies, possibly organic solar cells.

(2) Prior Art

A genre-forming device is generally known in professional circles and is frequently designated as a Grátzel cell after the inventor of U.S. Pat. No. 4,927,721 which discloses important structural features and photovoltaic or chemical details of the present technology which is assumed to be genre-forming. The core of such a cell is a titanium dioxide layer provided on an electrode, on which a dye layer (=DYE layer) is formed, on which in turn an electrolyte layer and a counter-electrode are formed. The external electrodes are typically implemented as thin conductive glass substrates (to allow entry of light into the cell), wherein use is made of the effect that due to the incident light, an electron is excited from the dye layer and enters into the conduction band of the TiO₂, thus achieving a state of charge separation. The charge in the conduction band is then fed via a load to the counter-electrode where a redox electrolyte is reduced which in turn lead to reduction of the (oxidised) dye. The diagram in FIG. 4 illustrates this fundamental process in a two-dimensional arrangement comprising a sequence or geometry of the individual steps in the horizontal and the energy level in the vertical.

For numerous applications, however, such a rigid arrangement (due to the conducting glass plate electrodes) is found to be too rigid and correspondingly inflexible so that attempts are also known to fabricate flexible DNSCs. On the one hand, for this purpose it was necessary to provide low-temperature processes (especially for application of the metal oxide semiconductor) so that polymeric substrates could be used instead of glass plates (titanium dioxide is typically applied at high temperatures which is incompatible with the use of plastics). Thus, attempts are being made to use polymer-based substrates, possibly in the form of conductingly coated PET (possibly ITO-PET, i.e. a conducting layer on PET, fabricated by indium-doped SnO₂). In the case of polymer-based substrate films, the conducting layers are restricted to transparent materials such as, for example, doped metal oxides, conducting polymers. Optically opaque coatings (such as metals, for example) can typically not be used. Another problem with (conducting) polymers used here is their unsuitably high sheet resistance as previously.

A further disadvantage of such considerations (initially only existing in principle) for fabricating flexible solar cells according to the DNSC principle is the mechanical problem that a bending between the so-called active layer (i.e. the conducting substrate, the titanium dioxide layer formed thereon and the dye layer) on the one hand and counter-electrode on the other hand leads to unstable conditions, caused by the displacement or shear at the contact face.

Finally, an important problem in the design of flexible SECMs is the fabrication of a stable, loadable and nevertheless flexible junction between the substrate and the metal oxide semiconductor material: the titanium dioxide typically selected as a result of its large effective surface area (having a surface roughness dimension between about 20 and 200, defined as the ratio of an effective surface area relative to the projected base area, e.g. by a nano-particle structure) lies in the inherent brittleness of the material with the associated mechanical stability problem. In particular, such a metal oxide layer thus adheres only poorly to a (conducting) polymer as support substrate.

It is therefore the object of the present invention to provide an improved photoelectric cell, in particular a solar cell of the DNSC type, which combines improved mechanical flexibility of the end product with favourable fabrication properties, advantageous photoelectric properties and good long-term stability. In addition, a cell is to be provided which can potentially be fabricated at low cost and is suitable for mass production, and allows high reproducibility of the photoelectric properties even outside the small-scale production or laboratory environment.

The object is achieved by the photovoltaic cell having the features of the main claim and the method for fabricating a photovoltaic cell according to the dependent claim 16; advantageous further development of the invention are described in the dependent claims.

In an advantageous manner according to the invention, using in principle the operating mode of the so-called Grátzel solar cell (possibly in accordance with U.S. Pat. No. 4,927,721 or EP-B0 525 070), a fabric is selected as the basis for the conductingly configured support substrate according to the invention (additionally or alternatively also for implementing the counter-electrode), wherein this flexible fabric makes it possible to achieve numerous surprising advantages for achieving the aforesaid object: even if a material which itself is not transparent is used for the fibres, the use of a fabric, more preferably a fabric with predetermined openings and/or fabric gaps, makes it possible to achieve an adjustable or predetermined and advantageous transparency of the support substrate and therefore potentially of the entire arrangement. Also, a fabric as such provides a potentially large effective surface area (possibly by means of the individual lateral surfaces of the fibres woven in the fabric), so that with subsequent coating of the metal oxide semiconductor material (itself in turn having a high surface area), an effective total area exists as the basis for the dye layer (preferably monomolecular) to be applied, whereby efficiency and stability can be optimised to achieve a high efficient not achieved hitherto. (In an advantageous manner according to a further development, the inherently high effective surface area of the fabric allows the metal oxide semiconductor material to be applied only as a very thin, preferably nano-particle and/or nano-structure coating with correspondingly positive effects on the efficiency—low dark due to shorter distance to the conducting layer of the substrate for the electron—and improved mechanical stability due to lower brittleness of the thin coating.) This configuration also makes it possible to effectively use a substantially larger spectrum of suitable dyes (in particular those having lower extinction coefficients).

In this case, the fabric used according to the invention allows numerous possible configurations to achieve these advantageous effects. On the one hand, the fabric is preferably formed from electrically non-conducting or weakly conducting fibres to which a suitably conducting coating is then applied, before or after the weaving, wherein according to a further development it is favourable to use carbon or (conducting) polymer fibres. On the other hand, suitable copper, titanium or aluminium fibres, for example, are used for conducting fibres.

According to a further development, the conducting layer applied to the fabric to achieve the support substrate (primarily in the case of non-conducting/weakly conducting fibres) can itself again be a (for example, suitably doped) metal oxide, a metal or a conducting polymer.

It is also particularly suitable to use the fabric itself to guide the lines required for supplying or leading off the charges to corresponding connecting electrodes of the solar cell; according to a preferred further development of the invention, this is achieved by weaving in these leads in the form of metal wires (which traditionally must be formed at some expense on the conducting glass plates of known solar cells) with the other fibres during the fabrication of the fabric within the scope of the further development according to the invention. In this way, in addition to favourable mechanical flexibility and connecting properties, favourable electrical contacting is also ensured (again with positive effects on the efficiency by reducing ohmic junction resistances).

As has already been described, within the scope of preferred embodiments of the invention, preferably nanostructured TiO₂ or ZnO (as examples) are used as metal oxide-semiconductor material since the optimisation between mechanical stability and elasticity with desired effective surface area described above can be achieved. Within the scope of preferred further developments of the invention with regard to process technology, this material is additionally dispersed in suitable solvents, applied to the fabric by impregnating and pressed after drying (volatilising the solvent). Other suitable methods which form a favourable join with the fabric without disadvantageously impairing this are possibly sintering, so-called sol-gel methods or sputtering.

Then within the scope of the invention, a thin dye layer, according to a further development, monomolecular, i.e., merely having the layer thickness of a dye molecule, is applied to the thus provided composite of (conducting) fabric-based fabric substrate with metal oxide-semiconductor layer, again by means of a suitable solution. Both Ru-based metal complexes and also organic dyes are suitable within the scope of the invention wherein, within the scope of selecting the dye layer, it is provided according to the invention that the energy levels of the dye, the semiconductor and the electrolyte are matched to one another, so that the desired photochemical and electrical processes can proceed in an optimised manner.

A further preferred embodiment of the present invention (best mode) provides that the electrolyte layer according to the invention (possibly by using an acrylate resin or another deformable and hardenable polymer) in a liquid or fluid state allows the deformation of the cells according to the invention into an approximately arbitrary, desired shape (in particular for adaptation to a provided usage environment, e.g. in the construction or building sector), whereupon this material can then be hardened and the shaping thereby permanently fixed in its configuration. For this purpose, the electrolyte layer suitably comprises a solvent, a redox pair and well as optionally additives which, in the manner possibly of the design with glass-fibre-reinforced plastics, can allow mechanically very stable units, and at the same time achieve the photochemical or photoelectric properties of a DNSC solar cell. Within the scope of suitable further developments of the invention, it is particularly provided that in addition to a suitable curability of the electrolyte provided with corresponding properties (in addition to thermally curing resin, UV curing resin also particularly comes into consideration here), such curing or permanent deformation is ensured by resins outside the electrolyte (which are therefore not connected to the electrolyte) acquiring such functionality, possibly by an additional outer resin layer which is then, in the manner according to this further development, brought into its permanent form by suitable formulation and the electrolyte material can be selected independently thereof.

Within the scope of a preferred further development of the invention, it is preferred with regard to the process technology to apply one or more layers by means of a screen printing method.

According to a further, preferred further development of the invention, it is provided to stack a plurality of cells according to the invention on their flat sides to create in this respect a very compact efficient multi-cell structure, possibly in the manner of a book with superposed pages.

Particularly suitable for this embodiment is a lateral incidence of light (i.e. incidence of light in the plane of the fabric), more preferably made by possible by possibly using light-guiding fibres as fibres for the fabric or films or thin glass layers through which light can then be introduced accordingly at the end or front side and, after suitable modification of the fibres or light guides, can emerge on the cladding side into the further photo-electrically active layers of the cell arrangement (according to the invention, a usual direction of the incidence of light from the side of the conducting support substrate is accomplished otherwise, which particularly suitably due to the fabric used according to the invention, is suitably transparent). It remains to be noted that an advantage of such an embodiment (corresponding to a book form) of the invention is that the substrates used need not be transparent. In addition, the encapsulation can be optimised since, in principle, the light-introducing layer can have any thickness and a suitable adjustment or control of the light incidence wavelength is also possible.

As a result, the present invention reveals in a surprisingly elegant and favourable manner in terms of production technology how flexible solar cells having favourable efficiency properties and excellent mechanical stability can be produced so that it can be expected that numerous new fields of use for photovoltaics can be opened up.

### BRIEF DESCRIPTION OF THE DRAWINGS

Further advantages, features and details of the invention are obtained from the following description of preferred exemplary embodiments and with reference to the drawings; in the figures:

FIG. 1: is a schematic, exploded cutaway side view of the layer structure of the photovoltaic cell according to a first preferred embodiment of the present invention;

FIG. 2: shows a diagram of the molecular structure of the dye (N719) used for the dye layer in the exemplary embodiment of FIG. 1;

FIG. 3: shows a current/voltage diagram to illustrate the electrical properties of the photovoltaic cell similar to FIG. 1; and

FIG. 4: shows a schematic diagram with an energy level and layer diagram to illustrate the fundamental operating mode of a DNSC.

### DETAILED DESCRIPTION OF THE PREFERRED EMBODIMENTS

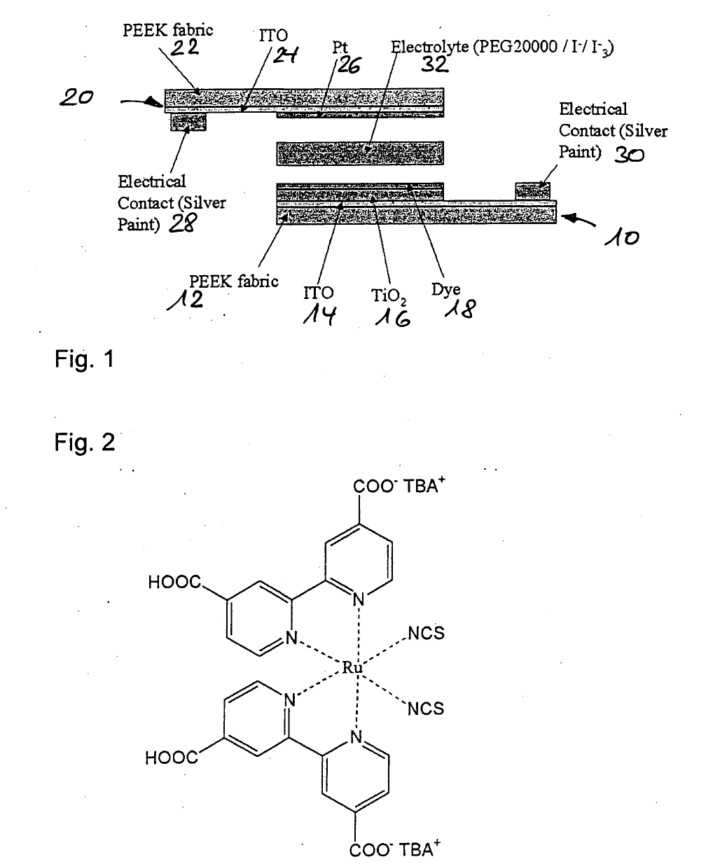

Furthermore, the structure and the fabrication of the photovoltaic cell according to a first preferred embodiment of the present invention are explained with reference to FIGS. 1 to 3. Since production aspects are also important to achieve the desired properties, in the following description each active layer according to FIG. 1 is described and linked in conjunction with relevant, particularly suitable fabrication steps.

In the exemplary embodiment of the photovoltaic cell in FIG. 1, a conductingly configured support substrate 10 comprises an underlying fabric layer 12 as PEEK fabric which is coated with indium-doped SnO₂ (=ITO) as a conducting layer 14 in an otherwise known manner.

A metal oxide-semiconductor layer of TiO₂ having a thickness of 1 to 20 μm is applied to these layers 12, 14, wherein for this purpose a 5 wt.% TiO₂ solution in ethanol was sprayed onto the ITO-modified fabric and after drying or vaporising the solvent, the coating was exposed to a pressure of about 15 000 min/cm² for a period of 10 sec to 10 min. Alternative methods for applying the semiconductor layer are (plasma) sputtering, corona+aerosol and screen printing.

The TiO₂ layer 16 is then provided with a light-absorbing dye layer 18 as a mono-molecular layer. In the present case, a ruthenium-metal complex having the structural formula according to FIG. 2 was used as dye N719 (Solaronix, CH-Arbonne), the application to the substrate coated with metal oxide-semiconductor material being effected such that the PEEK-TiO₂ substrate was introduced in a 3 mmol dye solution for four hours.

Provided opposite to the photo-electrically (and photochemically) constructed active layer 14, 16, 18 thus constructed is a counter-electrode 20 which in turn has a conducting PEEK/ITO substrate 22, 24 (about 100 nm) which is coated on the conductor side with a platinum layer of usual thickness. The platinising was specifically carried out by introducing the counter-electrode 20 into a 0.5 nM solution of H₂PtCl₆ in 2-propanol for a few seconds. After removing the counter-electrode from the solution, this was dried and heated for 10 minutes at a temperature of 200° C.

Both the counter-electrode 20 and also the photo-electrically active substrate 10 each have an electrical inlet or outlet in the form of an electrical contact electrode 28 or 30 which, in the exemplary embodiment shown, is formed by silver varnish but other suitable methods, in particular by weaving in suitable conducting fibres into the fabric 12, 22, can also be achieved. These leads 28, 30 are then used for external contact to the solar cell in FIG. 1.

An electrolyte of the type PEG20000 (Aldrich) in conjunction with LiI (0.1 M) and I₂ (0.01 M) has been used to achieve an electrolyte layer 32 to be provided between the respective coated electrodes (FIG. 1 shows an exploded view in schematic form). Since PEG20000 is solid at room temperature, melting was required for mixing with the active redox components.

In order to join the coated counter-electrode 20 to the photoelectrically coated substrate electrode 10, the electrolyte was applied in liquid form to the active layer of the electrode 10 (i.e. the dye surface 18) and the counter-electrode was placed thereon with the still-liquid electrolyte. After cooling and curing the electrolyte, an adhesive bonding of the entire layer arrangement was thus produced where care was taken to ensure that the contact electrodes 28, 30 did not come in contact with the electrolyte and no short circuit occurs between the two electrodes.

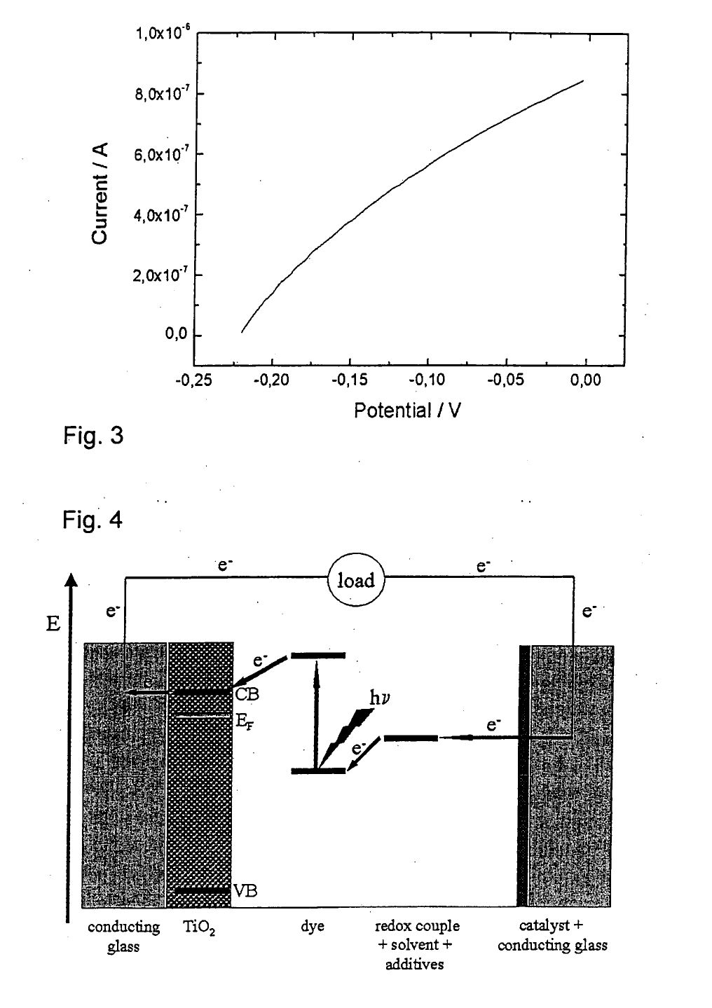

The current/voltage diagram in FIG. 3 shows the electrical behaviour of the photophotovoltaic cell thus produced in ambient light and at room temperature between the open circuit voltage and the short circuit current.

The present invention is not restricted to the exemplary embodiment show or to the process steps described. For example, the substrate can also consist of conducting material (Al fibres or optionally even coated carbon fibres) wherein the conductor layer 14 can be omitted if the electrical conduction properties are sufficient. In order to achieve the desired conductivity properties, this can in turn itself comprise a doped metal oxide as described in the exemplary embodiment, alternatively a metal (e.g. Ti or Al) or a conducting polymer (e.g. PDOT). A further variant for achieving the (main) electrode is to use so-called Carbotex, a fabric supplied by Sefar, CH-Thal, which comprises carbon-coated polyamide fibres and makes the ITO coating unnecessary due to its conductivity properties.

It is also possible to apply the metal oxide-semiconductor (instead of TiO₂, ZnO, for example can also be used) by sintering a corresponding powder, by the so-called sol-gel process or by sputtering.

Whereas a Ru-based metal complex was used as the dye layer, metal-free dyes are also possible, in the form of so-called organic dyes, possibly azo dyes, oligoenes, merocyanines or others.

Whereas the counter-electrode 20 in FIG. 1 exhibited a platination 26, an SnO₂ nano powder or the like can alternatively also be applied with comparatively good catalytic properties.

It should be borne in mind that the above description is only to be understood as exemplary and other suitable process steps and/or material are also possible for achieving the respective functionality of the individual layers.

In particular, a preferred further development of the invention provides to provide the electrolyte layer 32 with acrylate resin, polyethylene oxide or polyethylene glycol so that in the manner of a procedure during the processing of glass-fibre-reinforced plastics, the solar cell arrangement in the manner described according to the invention can be an integral component of various object and/or building components, wherein flexibility during processing can advantageously be combined with thermal stability and rigidity with simultaneously given transparency.

An alternative procedure for achieving the photovoltaic cell according to a second embodiment of the present invention is furthermore described as a sequence of the necessary or preferred steps according to the invention:
a) A fabric for the electrode (e.g. PEEK coated with ITO) and for the counter-electrode (e.g. Carbotex) is in each case cut to a size of 1.5×4 cm for producing the solar cell pattern and is brought in contact with respectively strip-shaped aluminium foil and fabric adhesive tape, whereby a strip of commercially available aluminium tape having a size of 0.8×6 cm is applied centrally to the adhesive surface of a strip of fabric adhesive tape (size 1×4 cm) so that the aluminium foil protrudes by 2 cm on a longitudinal side. The electrode fabric is applied to the adhesive surface or the aluminium foil, the protruding section of the aluminium foil is then folded down and pressed on. A fabric strip (PET 1000) is furthermore cut to dimensions of 0.8×4 cm as intermediate fabric. b) A 1M TTIP/ethanol solution is then prepared in an argon atmosphere and the electrode is sprayed by means of an EBFE airbrush pistol (Double Action CI model) (0.4 bar pre-pressure (argon), spraying distance to fabric about 10 cm, five spraying cycles twice on one side). Between the spraying cycles, the solvent is in each case vaporised on the fabric in the argon stream of the pistol.
c) Treating the arrangement in a miniclave, 10 ml doubly distilled water; heat treatment at 100° C. for 12 hours, then cooling to room temperature. The electrode is washed on both sides with ethanol and the fabric is dried for about 1 min in a warm air stream.
d) A 3 mmol dye solution (N719/absolute ethanol 100%) is prepared; the total dye should be dissolved (e.g. by means of an ultrasonic bath).
The electrode arrangement is then placed in this dye solution for about 3 hours, protected against light and moisture, and then removed, washed with ethanol and dried for about 1 min in a warm air stream.
e) The electrolyte is prepared as follows: 20 ml of acetonitrile (ACN, pure grade) with 0.0160 g TiO2 (about 10% to polyethylene oxide, Degussa P25), 1.3384 g LiI (0.5 M, purity 99.9%, Aldrich), 0.2538 g I2 (0.05 M, purity>=99.5%, Fluka). 0.16 g of polyethylene oxide (Mw=2000000, Fluka) is supplied over a period of 1 min. This electrolyte mixture is agitated at room temperature for 12 hours.
f) For mounting the solar cell, the electrolyte is concentrated on a hot plate at 100° C. until it is still highly flowable. The counter-electrode—if using a counter-electrode of Carbotex (Sefar), a further coating can optionally be omitted—is placed on a glass substrate, the intermediate fabric (step a) is coated on both sides by dipping in the heated electrolyte and placed on the counter-electrode. The electrode is dipped into the electrolyte to a depth of 1 mm and then placed thereon. By leaving the arrangement to stand (about 10 min), the electrolyte is cured and then treated in a warm air stream (about 1 min) so that residual solvent can evaporate. For sealing, clear varnish or a transparent resin can be applied to both sides whereby mechanical properties can again be adjusted, for example protection against weathering influences and/or permanent form fixing.

Comment: Carbotex can be used untreated as the counter-electrode. Otherwise, methods similar to method 1 can be used.

As a result, numerous advantages can be achieved with the present fabric-based technology. Due to the structure, even after coating with non-transparent material, the arrangement is still at least partially light-transmitting, in addition the flexibility achieved allows almost any fixing and curing on differently formed surfaces.

A substantially larger effective surface area can be achieved compared with film and not least because of the larger areas, the metal oxide-semiconductor layer (possibly TiO₂) can be correspondingly thinner (and therefore more flexile) with the further advantages of reduced delamination and lower material consumption. Thus, the electrical contact or outlet can easily be made by means of woven(−in) or sewn thread and the book structure which can be achieved according to a further development opens up additional areas of use and application.

1-20. (canceled)

21. A photovoltaic cell comprising:
a conductingly configured support substrate which is coated with a metal oxide semiconductor layer;
a dye layer configured for electronic interaction with the metal oxide semiconductor layer;
an electrolyte layer located in the dye layer;
a counter-electrode connected to the electrolyte layer; and
at least one of the support substrate and the counter-electrode being made from a flexible fabric woven from a plurality of fibers.

22. The cell according to claim 21, wherein the fibers consist of an electrically conducting material.

23. The cell according to claim 21, wherein the fibers comprise an electrically conducting coating on an electrically non-conducting or weakly conduction core made of a material selected from the group consisting of a polymer, glass, ceramic and composite material.

24. The cell according to claim 21, wherein the fibers are selected from the group consisting of carbon fibers, fibers of conducting polymers, metal fibers, Al fibers and combinations thereof.

25. The cell according to claim 21, wherein the fabric is coated with a conducting layer to achieve the conductingly configured support substrate.

26. The cell according to claim 25, wherein the conducting layer comprises at least one of a doped metal oxide, a metal and an electrically conducting polymer.

27. The cell according to claim 21, wherein the fabric comprises at least one woven-in electrically conducting fiber for supplying or leading off the current generated by the photovoltaic cell to a connecting electrode.

28. The cell according to claim 21, wherein the fabric comprises a plurality of predetermined fabric gaps and/or openings to achieve a partial transparency of the support substrate, and wherein a width of each fabric gap is between 50 μm and 500 μm.

29. The cell according to claim 21, wherein the metal oxide semiconductor layer comprises a nanostructured and/or applied TiO₂ and/or ZnO and/or BaTiO₃.

30. The cell according to claim 21, wherein the metal oxide semiconductor layer is applied by pressing-in and/or pressing-on a solution of the metal-semiconductor material into the fabric, by sintering, by a sol-gel process, by corona aerosol, by screen printing or by plasma sputtering.

31. The cell according to claim 21, wherein the dye layer has a thickness in the molecular range and is applied as a mono-particle and/or as nano-structured.

32. The cell according to claim 21, wherein a dye of the dye layer comprises a preferably Ru-based metal complex and/or an organic dye selected from the group consisting of azo dyes, oligoenes, merocyanines and mixtures thereof.

33. The cell according claim 21, wherein the electrolyte layer comprises a deformable and hardenable material and wherein the material is deformable for forming into a predetermined shape and can subsequently be hardened into said shape by curing.

34. The cell according to claim 33, wherein the deformable and hardenable material is an acrylate resin.

35. The cell according to claim 33, where the deformable and hardenable material is provided on the photovoltaic cell outside the electrolyte layer.

36. The cell according to claim 33, wherein the deformable and hardenable material is provided in the photovoltaic cell outside the electrolyte layer.

37. The cell according to any claim 21, wherein said cell is configured to be fabricated by successively coating a plurality of cells as a multiple coating and wherein a preferred direction of the incidence of light on the cell is provided perpendicular to the multiple coating.

38. The cell according to claim 37, wherein the multi-layer arrangement comprises different dyes having different absorption spectra in each respective dye layer.

39. The cell according to claim 21, wherein the fabric comprises light-conducting fibers as fibers which are configured so that light can be introduced into the fibers at the front.

40. A method for fabricating a photovoltaic cell comprising the steps of:
coating a conductingly configured fabric with a metal oxide semiconductor layer;
applying a dye layer configured for electronic interaction with the metal oxide semiconductor layer;
applying an electrolyte layer to the dye layer; and
applying a counter-electrode to the electrolyte layer.

41. The method according to claim 40, further comprising applying the metal oxide-semiconductor layer in emulsified form, by plasma sputtering, by a sol gel method and/or by pressing-on and/or pressing-in to the fabric.

42. The method according to claim 40, further comprising applying a dye of the dye layer in dissolved form and with an application thickness in the molecular range to the metal oxide-semiconductor layer.

43. The method according to claim 40, wherein the electrolyte layer applying step comprises applying the electrolyte layer in a fluid state to the counter-electrode and to a composite of fabric, metal oxide-semiconductor layer and dye layer and subsequently hardening the electrolyte layer.

44. The method according to claim 43, wherein the hardening step comprises effecting the hardening by hardening the electrolyte layer and/or an additionally used polymer outside the electrolyte layer, after deforming the entire arrangement into a predetermined shape.
